(19) United States
(12) Patent Application Publication
(10) Pub. No.: US 2007/0176279 A1
(43) Pub. Date: Aug. 2, 2007

(54) Circuit board, semiconductor package having the same, and method of manufacturing the circuit board

(75) Inventor: Kil-Soo Kim, Asan-si (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 11/654,586

(22) Filed: Jan. 18, 2007

(30) Foreign Application Priority Data
Jan. 31, 2006 (KR) 10-2006-0009224

(51) Int. Cl. H01L 23/48

(52) U.S. Cl. 257/690

(57) ABSTRACT

A circuit board may include an insulation plate having at least one slot. A first conductive pattern may be on the insulation plate. A plug may be on a sidewall of the slot, and may be electrically connected to the conductive pattern.

### PRIORITY STATEMENT

This U.S. non-provisional application claims benefit of priority under 35 U.S.C. §119 to Korean Patent Application No. 2006-9224, filed on Jan. 31, 2006 in the Korean Intellectual Property Office (KIPO), the entire contents of which are herein incorporated by reference.

### BACKGROUND

1. Field

Example embodiments relate to a circuit board, a semiconductor package having the circuit board, and a method of manufacturing the circuit board. For example, a circuit board including a conductive pattern, which may serve as a wiring connected to a power source, a ground, or signals.

2. Description of the Related Art

Generally, a semiconductor device may be manufactured through a semiconductor chip fabrication process, an electrical die sorting (EDS) process, a packaging process, and a mounting process. In the semiconductor chip fabrication process, a semiconductor chip including an integrated circuit (IC) mounted on a silicon wafer may be fabricated. In the EDS process, the semiconductor chip may be electrically inspected and sorted. In the packaging process, the semiconductor chip may be encapsulated in order to protect against external impacts or changes. In the mounting process, the semiconductor package may be mounted on a circuit board.

Recently, semiconductor devices have been developed to have a higher capacity and a higher degree of integration. In order to manufacture a semiconductor device having a higher capacity and a higher degree of integration, different packaging techniques may be needed because various properties of the semiconductor device, for example, size, heat emission capability, electrical performance, reliability, and/or manufacturing cost, may be greatly varied according to the packaging technique used.

Packaging techniques including single inline packages (SIP's), dual inline packages (DIP's), quad flat packages (QFP's) and ball grid arrays (BGA's) have been developed. Recently, chip-scale packages (CSP's), multi-chip packages (MCP's), stacked CSP's (SCSP's), and wafer-level CSP's (WLCSP's) have been developed in order to enhance mounting efficiency per unit volume of the semiconductor devices. Additionally, wafer-level packages (WLP's) have been developed which may be fabricated by cutting an already manufactured wafer having semiconductor chips mounted thereon.

Over the years, the packaging techniques have been developed to manufacture lighter, thinner, shorter and smaller semiconductor packages. As a result, the size of semiconductor chips mounted on a circuit board has been gradually decreased, whereas the number of terminals in the semiconductor chip has been increased. Accordingly, space for conductive patterns connecting the semiconductor chip to the circuit board may have been gradually reduced.

FIG. 1 is a bottom view of a conventional semiconductor package.

Referring to FIG. 1, a semiconductor package may include a circuit board 10, a semiconductor chip 40 and an external terminal 50.

A slot 15 may be formed through the circuit board 10, and the semiconductor chip 40 may be disposed over the slot 15. The slot 15 may have a size smaller than a size of the semiconductor chip 40, and thus the semiconductor chip 40 may be disposed on a top face of the circuit board 10 and may cover the slot 15. Terminals 45 of the semiconductor chip 40 may be exposed through the slot 15.

A plurality of external terminals 50 may be formed on a bottom face of the circuit board 10. Each of the external terminals 50 may apply power to the semiconductor chip 40, ground the semiconductor chip 40, input electrical signals into the semiconductor chip 40, and/or receive electrical signals output from the semiconductor chip 40. Each of the external terminals 50 may be electrically connected to the semiconductor chip 40 through a conductive pattern 20 and a bonding wire 47.

The conductive pattern 20 may be extended from the external terminal 50 to a region around the slot 15. The bonding wire 47 may be connected to the conductive pattern 20 formed in the region around the slot 15, and may be extended to the terminals 45 of the semiconductor chip 40. Thus, the power supplied by the external terminal 50 or the electrical signals output from the external terminal 50 may be provided to the semiconductor chip 40. Additionally, electrical signals output from the semiconductor chip 40 may be provided to the external terminal 50, and the semiconductor chip 40 may be grounded through the external terminal 50.

A plurality of conductive patterns 20 may be formed around the slot 15, and may serve as wirings for grounding the semiconductor chip 40 and for transferring power or signals between the semiconductor chip 40 and the external terminal 50. If the size of the slot 15 is reduced corresponding to a reduction in size of the semiconductor chip 40, a space for the conductive patterns 20 may be reduced. However, a technique has been developed in which the conductive patterns 20 formed on the bottom face of the circuit board 10 may be extended to the top face of the circuit board 10 through a plug 30.

If the plurality of the conductive patterns 20 are formed on both the top and bottom faces of the circuit board 10 according to the above-mentioned technique, the space for the conductive patterns 20 may be increased, and mutual capacitances and mutual inductances between each of the conductive patterns 20 may be decreased so that the semiconductor chip 40 may operate more stably.

However, the plug 30 may be formed in the space for the plurality of the conductive patterns 20 disposed on the bottom face of the semiconductor chip 40 which may decrease the space for the conductive patterns 20. For example, a diameter of the plug 30 may be at least about 5 times as large as a width of the conductive pattern 20, thereby requiring more space in which to form the plug 30.

Additionally, because the plug 30 may be formed in the space for the conductive patterns 20 disposed on the bottom face of the circuit board 10, the plurality of the conductive patterns 20 may be formed around the plug 30. Thus, the conductive patterns 20 may have increased lengths and bent shapes which may cause the transferring capacity of the conductive patterns 20 to be deteriorated, thus causing instability in operations of the semiconductor chip 40.

The size of the semiconductor chip 40 may be reduced to a range of about a few mm² to about a few dozens of mm², and the size of the slot 15 and the space for the conductive patterns 20 may be accordingly reduced. Therefore, techniques may be being pursued by which the conductive patterns 20 may be effectively disposed in a small space and/or by which the decrease in the space for the conductive patterns 20 may be minimized.

### SUMMARY

Example embodiments may provide a circuit board, a semiconductor package including a circuit board, and a method of making a circuit board, that may secure a larger space for conductive patterns on the circuit board so that mutual interferences in the conductive patterns may be reduced.

Example embodiments may provide a circuit board, a semiconductor package including a circuit board, and a method of making a circuit board, that may have more stable and more efficient operation capacity.

In an example embodiment, a circuit board may include an insulation plate having at least one slot, a first conductive pattern on the insulation plate, and a plug in the insulation plate along a sidewall of the slot and electrically connected to the first conductive pattern.

According to an example embodiment, the plug may be received in a hole in the insulation plate along the sidewall of the slot.

According to an example embodiment, the plug may have a shape corresponding to the hole.

According to an example embodiment, the plug may fill the hole.

According to an example embodiment, the plug may have a semi-circular cylindrical shape.

According to an example embodiment, the plug may protrude from the sidewall of the hole.

According to an example embodiment, the insulation plate may include a first conductive pad electrically connecting the first conductive pattern to an external terminal that may be formed on the first conductive pad.

According to an example embodiment, the external terminal may be one of a power terminal for applying power to the first conductive pattern, a ground terminal for grounding the first conductive pattern, and a signal terminal for inputting electrical signals into the first conductive pattern or receiving electrical signals output from the first conductive pattern.

According to an example embodiment, the first conductive pattern may include a first conductive line on an upper surface of the insulation plate electrically connected to an upper end of the plug, a second conductive line on a lower surface of the insulation plate electrically connected to the first conductive pad, and a contact plug through the insulation plate electrically connecting the first conductive line and the second conductive line.

According to an example embodiment, a bond finger may be on the lower surface of the insulation plate and may be electrically connected to a lower end of the plug. The bond finger may be configured to be electrically connected to a terminal of a semiconductor chip.

According to an example embodiment, the conductive pattern may be in the insulation plate.

According to an example embodiment, the insulation plate may include a plurality of slots and a plurality of conductive patterns, and at least one of the plurality of conductive patterns may be disposed between at least two of the plurality of slots.

According to an example embodiment, a second conductive pattern may be on the lower surface of the insulation plate.

According to an example embodiment, the insulation plate may include a second conductive pad electrically connecting the second conductive pattern to an external terminal that may be formed on the second conductive pad.

According to an example embodiment, a semiconductor package may include the circuit board. A semiconductor chip may be disposed on the circuit board. A connecting terminal of the semiconductor chip may be exposed through the slot and the connecting terminal may be electrically connected to the plug.

According to an example embodiment a molding member may be on the circuit board covering the semiconductor chip.

According to an example embodiment, the conductive pattern may include a power wire for applying power to the semiconductor chip, a ground wire for grounding the semiconductor chip, and a signal wire for inputting electrical signals to the semiconductor chip or receiving electrical signals outputted from the semiconductor chip.

According to an example embodiment, the first conductive pattern may be one of a power wire for applying power to the semiconductor chip, a ground wire for grounding the semiconductor chip, and a signal wire for inputting electrical signals to the semiconductor chip or receiving electrical signals output from the semiconductor chip.

According to an example embodiment, the insulation plate may include a plurality of slots and a plurality of conductive patterns, and at least one of the plurality of conductive patterns may be disposed between at least two of the plurality of slots.

According to an example embodiment, the insulation plate may include a third conductive pad electrically connected to the first conductive pattern. An external terminal may be on the third conductive pad.

In an example embodiment, a method of manufacturing the circuit board may include forming a first conductive pattern on an insulation plate. A plug may be formed through the insulation plate and may be electrically connected to the first conductive pattern. The plug may be exposed by forming at least one slot through the insulation plate.

According to an example embodiment, forming the plug may include forming a hole through the insulation plate and forming the plug in the hole using a conductive material.

According to an example embodiment, forming the slot may include removing a portion of the plug.

According to an example embodiment, a first conductive pad may be formed on the insulation plate. The first conductive pad may electrically connect the first conductive pattern to an external terminal that may be formed on the first conductive pad.

According to an example embodiment, forming the first conductive pattern may include forming a first conductive line on an upper surface of the insulating plate electrically connected to an upper end of the plug; forming a second conductive line on a lower surface of the insulating plate electrically connected to the first conductive pad; and forming a contact plug through the insulation plate electrically connecting the first conductive line and the second conductive line.

According to an example embodiment, a bond finger may be formed on the lower surface of the insulation plate. The bond finger may be configured to be electrically connected to a lower end of the plug and a connecting terminal of a semiconductor chip.

According to an example embodiment, a second conductive pattern may be formed on the lower surface of the insulation plate.

According to an example embodiment, a second conductive pad may be formed on the insulation plate. The second conductive pad may electrically connect the second conductive pattern to an external terminal that may be formed on the second conductive pad.

### BRIEF DESCRIPTION OF THE DRAWINGS

Example embodiments will be described with reference to the accompanying drawings.

FIG. 1 is a bottom view of a conventional semiconductor package.

FIG. 2 is a cross-sectional view of a circuit board in accordance with an example embodiment.

FIG. 3 is an enlarged perspective view of a portion A in FIG. 2.

FIG. 4 is a bottom view of the circuit board in FIG. 2.

FIG. 5 is a bottom view of a circuit board in accordance with another example embodiment.

FIG. 6 is a cross-sectional view of a semiconductor package in accordance with an example embodiment.

FIG. 7 is a bottom view of the semiconductor package in FIG. 6.

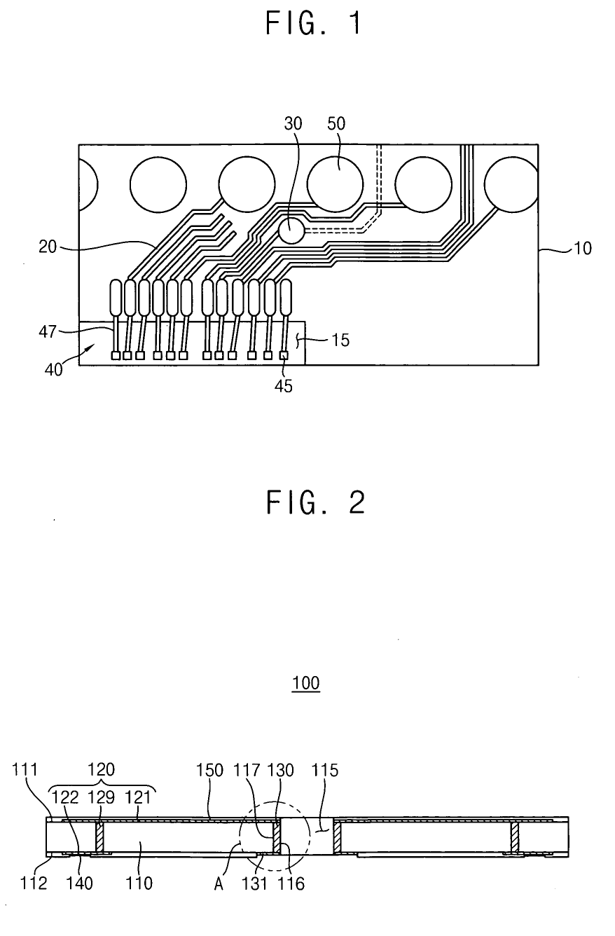

### DESCRIPTION OF EXAMPLE EMBODIMENTS

Example embodiments are described more fully hereinafter with reference to the accompanying drawings. Example embodiments may, however, be embodied in many different forms and should not be construed as limited to example embodiments set forth herein. Rather, these example embodiments are provided so that this disclosure will be thorough, and will fully convey the scope to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

It will be understood that, although the terms first, second, third, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular example embodiments only and is not intended to be limiting. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized example embodiments (and intermediate structures). As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the.

Unless otherwise defined, all terms (including technical and scientific terms) used herein have the same meaning as commonly understood by one of ordinary skill in the art. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

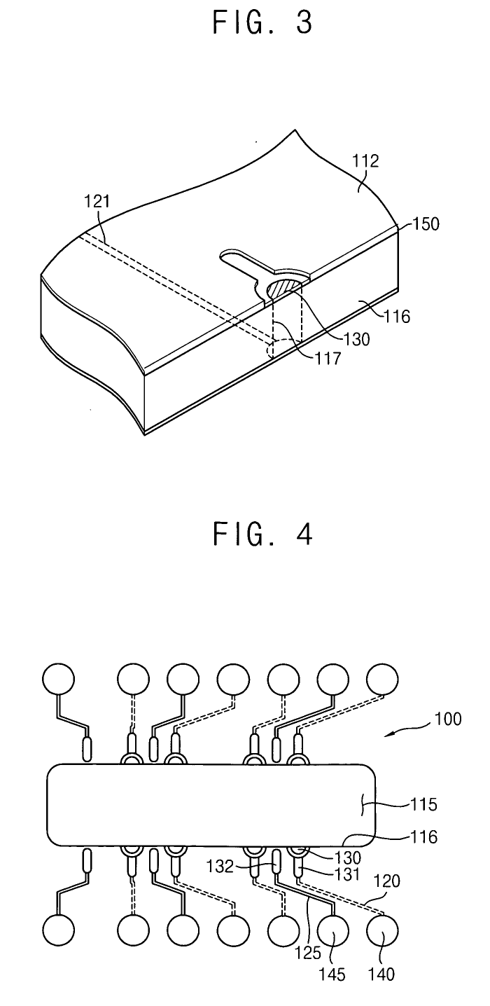

FIG. 2 is a cross-sectional view of a circuit board in accordance with an example embodiment. FIG. 3 is an enlarged perspective view of a portion A in FIG. 2. FIG. 4 is a bottom view of the circuit board in FIG. 2.

Referring to FIGS. 2 through 4, a circuit board 100 may apply power to a semiconductor chip (not shown), ground the semiconductor chip, input electrical signals into the semiconductor chip and/or receive electrical signals output from the semiconductor chip. The circuit board 100 may include an insulation plate 110, a first conductive pattern 120, a second conductive pattern 125, and/or a plug 130.

The insulation plate 110 may be formed to have a predetermined or desired thickness, and the thickness of the insulation plate 110 may be varied in accordance with desired impedances or inductances of the first and second conductive patterns 120 and 125. For example, the insulation plate 110 may be a single-layer or a multi-layer. The insulation plate 110 may have a slot 115 that may be formed through the insulation plate 110.

The slot 115 formed through the insulation plate 110 may serve as a passage for a connecting wire (not shown) that may electrically connect the semiconductor chip to the first and second conductive patterns 120 and 125. The connecting wire may be extended from the semiconductor chip to the first and second conductive patterns 120 and 125 through the slot 115.

The slot 115 may be formed in various portions of the insulation plate 110. A size of the slot and number of the slots may vary according to the semiconductor chip. For example, if the semiconductor chip is disposed on a central portion of the circuit board 100, the slot 115 may be formed in a central portion of the insulation plate 110. The size of the slot 115 may be smaller than a size of the semiconductor chip. If a plurality of the semiconductor chips is formed on the circuit board 100, a plurality of the slots 115 may be formed under each of the plurality of the semiconductor chips through the insulation plate 110.

In an example embodiment, one slot 115 may be formed in the central portion of the insulation plate 110. However, example embodiments may be embodied in many different forms and should not be limited thereto.

The plug 130 may be formed on a sidewall 116 of the slot 115. For example, the plug 130 may be formed in a semi-circular cylindrical shape. A hole 117 having a semi-circular cylindrical shape may be formed on the sidewall 116 of the slot 115 and the hole 117 may be filled with the plug 130.

The hole 117 may be formed in various shapes, for example, a square column and a circular cylinder which contacts the sidewall 116 of the slot 115, and a partial circular cylinder. If the hole 117 is formed in the circular cylindrical shape which contacts the sidewall 116 of the slot 115, a portion of circumference of the hole 117 may be substantially coincident with a portion of the sidewall 116 of the slot 115. If the hole 117 is formed in the partial circular cylindrical shape, the hole 117 may have a shape in between a circular cylinder and a semi-circular cylinder, for example, a circular cylinder in which a portion is vertically removed.

In an example embodiment, the plug 130 may be formed to fill up the hole 117 so that the plug 130 may have a shape corresponding to that of the hole 117. In another example embodiment, the plug 130 may be formed on a sidewall of the hole 117 as a thin film. In another example embodiment, the plug 130 may be formed on the sidewall 116 of the slot 115 so that the plug 130 may have a shape protruding from the sidewall 116 of the slot 115, and which may have a predetermined or desired width and thickness.

The plug 130 may include a conductive material. For example, the plug 130 may include gold, copper, and/or nickel. A top end of the plug 130 may be electrically connected to the first conductive pattern 120, and a bottom end of the plug 130 may be electrically connected to a first bond finger 131. The first bond finger 131 may be formed on a bottom face 112 of the insulation plate 110 and may be electrically connected to the connecting wire extended from the semiconductor chip.

The first conductive pattern 120 may include a first conductive line 121, a second conductive line 122, and/or a contact plug 129. The first conductive line 121 may be formed on a top face 111 of the insulation plate 110, and the second conductive line 122 may be formed on the bottom face 112 of the insulation plate 110. For example, the first and second conductive lines 121 and 122 may have a planar shape. The first and second conductive lines 121 and 122 may be electrically connected to each other through the contact plug 129 which may be formed through the insulation plate 110.

The second conductive line 122 may be electrically connected to a first landing pad 140. A first external terminal (not shown), for example, a solder ball, may be connected to the landing pad 140. The first external terminal may be a power terminal for applying power to the conductive pattern 120, a ground terminal for grounding the first conductive pattern 120, or a signal terminal for inputting electrical signals to or receiving electrical signals output from the first conductive pattern 120. The second conductive line 122 may serve as a power wire, a ground wire, or a signal wire depending on the type of the first external terminal. Similarly, the first conductive line 121 may serve as a power wire, a ground wire, or a signal wire depending on the type of the first external terminal.

As described above, the first bond finger 131 may be electrically connected to the first landing pad 140 through the plug 130 and the first conductive pattern 120. The first conductive pattern 120 may be disposed on the top face 111 of the insulation plate 110 so that a space for the second conductive pattern 125 may be secured on the bottom face 112 of the insulation plate 110.

The second conductive pattern 125 may be formed on the bottom face 112 of the insulation plate 110. The second conductive pattern 125 may be extended from a second landing pad 145 to a second bond finger 132. The second bond finger 132 may be formed close to or near the slot 115. The second bond finger 132 may be electrically connected to the connecting wire which may be extended from the semiconductor chip.

A second external terminal (not shown), for example, a solder ball, may be connected to the second landing pad 145. The second external terminal may serve as a power terminal for applying power to the second conductive pattern 125, a ground terminal for grounding the second conductive pattern 125, or a signal terminal for inputting electrical signals to or receiving electrical signals output from the second conductive pattern 125. The second conductive pattern 125 may serve as a power wire, a ground wire, or a signal wire depending on the type of the second external terminal.

A plurality of the first and second conductive patterns 120 and 125 may be formed on the insulation plate 110. Accordingly, a plurality of the plugs 130 and a plurality of the first and second landing pads 140 and 145 may be formed through and/or on the insulation plate 110.

According to some example embodiments, as described above, the plug 130 may be formed on the sidewall 116 of the slot 115 so that a space for the second conductive pattern 125 may be secured on the bottom face 112 of the insulation plate 110. For example, the first and second conductive patterns 120 and 125 may be disposed on the insulation plate 110 without mutual interferences between each other. Thus, the first and second conductive patterns 120 and 125 may transfer a higher frequency current to the semiconductor chip.

A protecting layer 150, for example, a photo solder resist, may be formed on the insulation plate 110 and may cover the first and second conductive patterns 120 and 125 and the plug 130. The protecting layer 150 may protect the first and second conductive patterns 120 and 125 and the plug 130 from possible impacts or changes from outside. An opening (not shown) may be formed in the protecting layer 150 to partially expose the first and second conductive patterns 120 and 125 and the first and second landing pads 140 and 145.

A method of manufacturing a circuit board, according to an example embodiment, may include preparing an insulation plate 110 having a predetermined or desired thickness. For example, the insulation plate 110 may be formed to have a single-layer or multi-layered structure. Metal layers may be arranged on the top and bottom faces of the insulation plate 110 for the first and second conductive patterns 120 and 125 that may be subsequently formed.

A hole 117 may be formed through the insulation plate 110. In an example embodiment, the hole 117 may be formed to have a circular cylindrical shape. The hole 117 may be formed through a portion of the insulation plate 110 so that a center of the hole 117 may be disposed at a sidewall 116 of a slot 115 that may be subsequently formed. In another example embodiment, the hole 117 may be formed through a portion of the insulation plate 110 so that a circumference of the hole 117 may touch or be disposed adjacent to the sidewall 116 of the slot 115 that may be subsequently formed. In another example embodiment, the hole 117 may be formed to have a shape, for example, a square column, a semi-circular cylinder, or a partial circular cylinder which may be a shape in between a circular cylinder and a semi-circular cylinder.

In an example embodiment, a plug 130 may be formed to fill the hole 117. The plug 130 may be formed by pressing a conductive material onto the hole 117. The plug 130 may be formed to have a shape corresponding to the hole 117. For example, if the hole 117 has a shape, for example, a semi-circular cylinder, a square column, or a circular cylinder, the plug 130 may have a corresponding shape. In another example embodiment, the plug 130 may be formed on the sidewall of the hole 117 as a thin film. The plug 130 may be formed by coating a conductive material onto the sidewall of the hole 117.

A first bond finger 131 may be formed on the bottom face 112 of the insulation plate 110 and may make contact with a bottom end of the plug 130. The first bond finger 131 may connect the plug 130 to the semiconductor chip.

A contact plug 129 may be formed through the insulation plate 110. The contact plug 129 may be formed to vertically penetrate through the insulation plate 110. For example, a contact hole (not shown) may be formed through the insulation plate 110 and a conductive material may filled into the contact hole to form the contact plug 129.

First and second conductive patterns 120 and 125 may be formed on the top and bottom surfaces 111 and 112 of the insulation plate 110, respectively, to make contact with the contact plug 129. The first and second conductive patterns 120 and 125 may have various shapes. For example, each of the first and second conductive patterns 120 and 125 may have a planar shape.

The first conductive pattern may include a first conductive line 121 formed on the top surface 111 of the insulation plate 110, and a second conductive line 122 formed on the bottom surface 112 of the insulation plate 110. The first conductive line 121 may be formed to make contact with the plug 130 so that the first conductive line 121 may be electrically connected to the plug 130, and the first and second conductive lines 121 and 122 may be electrically connected to each other through the contact plug 129.

A first landing pad 140 may be formed on the bottom surface 112 of the insulation plate 110 and may make contact with the second conductive line 122. Thus, the first landing pad 140 may be electrically connected to the second conductive line 122. A first external terminal, for example, a solder ball, may be connected to the first landing pad 140. The first external terminal may serve as a power terminal for applying power to the first conductive pattern 120, a ground terminal for grounding the first conductive pattern 120, or a signal terminal for inputting electrical signals to or receiving electrical signals output from the first conductive pattern 120. The second conductive line 122 may serve as a powerwire, a ground wire, or a signal wire depending on the type of the first external terminal.

The second conductive pattern 125 may be formed on the bottom surface 112 of the insulation plate 110. A second landing pad 145 may be formed on the bottom surface 112 of the insulation plate 110 to make contact with a first end of the second conductive pattern 125 so that the second landing pad 145 may be electrically connected to the second conductive pattern 125. A second bond finger 132 may be formed on the bottom surface 112 of the insulation plate 110 and may make contact with a second end of the second conductive pattern 125 so that the second bond finger 132 may be electrically connected to the second conductive pattern 125. The second bond finger 132 may be formed close to or near the slot 115.

A second external terminal, for example, a solder ball, may be connected to the second landing pad 145. The second external terminal may serve as a power terminal for applying power to the second conductive pattern 125, a ground terminal for grounding the second conductive pattern 125, or a signal terminal for inputting electrical signals to or receiving electrical signals output from the second conductive pattern 125. The second conductive pattern 125 may serve as a power wire, a ground wire, or a signal wire depending on the type of the second external terminal.

The first and second conductive patterns 120 and 125 may be formed by etching the metal layers that may have been previously formed on the top and bottom surfaces 111 and 112 of the insulation plate 110.

A slot 115 may be formed through the insulation plate 110 to vertically divide the plug 130. For example, if the plug 130 having a circular cylinder shape is vertically cut while forming the slot 115, the plug 130 may be transformed to a semi-circular cylinder shape on the sidewall 116 of the slot 115. If the plug 130 having a ring cylinder shape is vertically cut while forming the slot 115, the plug 130 may be transformed to a semi-ring cylinder shape on the sidewall 116 of the slot 115.

The protecting layer 150, for example, a photo solder resist, may be formed on the insulation plate 110 and may cover the first and second conductive patterns 120 and 125 and the plug 130. The protecting layer 150 may be formed on the sidewall 116 of the slot 115. An opening may be formed in the protecting layer 150 to partially expose the first and second conductive patterns 120 and 125 and the first and second landing pads 140 and 145.

In an example embodiment, the slot 115 may be formed through the insulation plate 110 after forming the plug 130 in the insulation plate 110. In another example embodiment, the plug 130 may be formed in the insulation plate 110 after forming the slot 115 through the insulation plate 110. In another example embodiment, the slot may be formed during the forming of the circuit board 100. Those skilled in the art may devise various modifications without departing from a scope of the foregoing description.

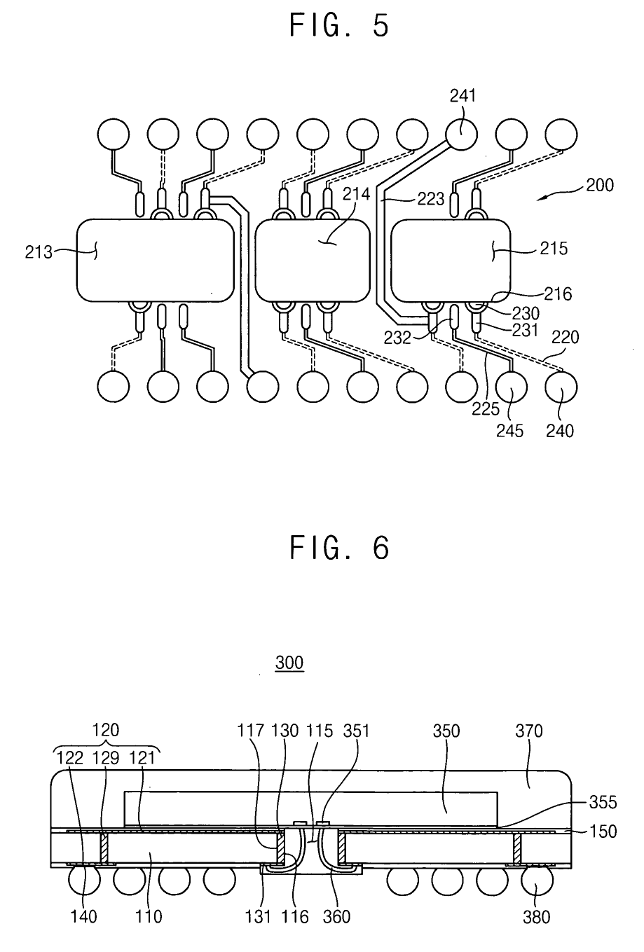

FIG. 5 is a bottom view of a circuit board in accordance with another example embodiment.

Referring to FIG. 5, a circuit board 200 may include an insulation plate (not shown), a first conductive pattern 220, a second conductive pattern 225, a sub-conductive pattern 223 and/or a plug 230.

The insulation plate may include a first slot 215, a second slot 214 and a third slot 213, all of which may be formed through the insulation plate.

A hole (not shown) that may have a semi-circular cylindrical shape may be formed on a sidewall 216 of the first slot 215, and the hole may be filled with a plug 230. The hole may be formed in various shapes, for example, a square column, a circular cylinder, or partial circular cylinder that may be a shape in between a circular cylinder and a semi-circular cylinder.

In an example embodiment, the plug 230 may be formed to fill up the hole so that the plug 230 may have a shape corresponding to that of the hole. In another example embodiment, the plug 230 may be formed on a sidewall of the hole as a thin film. In another example embodiment, the plug 230 may be formed on the sidewall 216 of the first slot 215 so that the plug 230 may have a shape protruding from the sidewall 216 of the first slot 115, and may have a predetermined or desired width and thickness.

The plug 230 may include a conductive material and be electrically connected to the first conductive pattern 220. For example, a top end of the plug 230 may be electrically connected to the first conductive pattern 220, and a bottom end of the plug 230 may be electrically connected to a first bond finger 231. The first conductive pattern 220 may serve as a power wire, a ground wire, or a signal wire depending on the type of a first external terminal (not shown), for example, a solder ball, which may be connected to a first landing pad 240.

The sub-conductive pattern 223 may be connected to the first bond finger 231. The sub-conductive pattern 223 may be disposed between the first and second slots 215 and 214. The first and third landing pads 240 and 241 may be positioned to face each other on opposite sides of the first slot 215. The sub-conductive pattern 223 may connect the first and third landing pads 240 and 241 to the plug 230 so that characteristics, for example, transferring power, grounding and transferring signals to the circuit board 100, may be improved. For example, if first external terminals (not shown) for applying power to a semiconductor chip (not shown) are connected to the first and third landing pads 240 and 241, the power may be transferred not only through the first conductive pattern 220 but also through the sub-conductive pattern 223 so that the capacity to transfer power may be strengthened. If first external terminals (not shown) for grounding the semiconductor chip are connected to the first and third landing pads 240 and 241, the semiconductor chip may be grounded through both of the first conductive pattern 220 and the sub-conductive pattern 223 so that the grounding capacity may be improved. If first external terminals (not shown) for transferring signals to the semiconductor chip are connected to the first and third landing pads 240 and 241, the signals may be transferred through both of the first conductive pattern 220 and the sub-conductive pattern 223 so that the capacity to transfer the signals may be improved.

The second conductive pattern 225 may be formed on a bottom face of the insulation plate. The second conductive pattern 225 may be extended from a second landing pad 245 to a second bond finger 232. The second bond finger 232 may be electrically connected to a connecting wire that may be extended from the semiconductor chip.

A second external terminal (not shown), for example, a solder ball, may be connected to the second landing pad 245. The second external terminal may serve as a power terminal for applying power to the semiconductor chip, a ground terminal for grounding the second conductive pattern 225, or a signal terminal for inputting electrical signals to or receiving electrical signals output from the second conductive pattern 225. The second conductive pattern 225 may serve as a power wire, a ground wire, or a signal wire depending on the type of the second external terminal. The above-mentioned sub-conductive pattern 223 may be connected to the second bond finger 232.

A plurality of the first and second conductive patterns 220 and 225 and the sub-conductive pattern 223 may be formed around the first slot 215 on the insulation plate 110. Accordingly, a plurality of the above plugs 230 may be formed through the insulation plate 110 and the first and second landing pads 240 and 245 may be formed on the insulation plate 110.

A plurality of the above first and second conductive patterns 220 and 225 and the above sub-conductive pattern 223 may be formed around the second and third slots 214 and 213 on the insulation plate 110. Accordingly, a plurality of the above plugs 230 may be formed through the insulation plate 110 and the first and second landing pads 240 and 245 may be formed on the insulation plate 110.

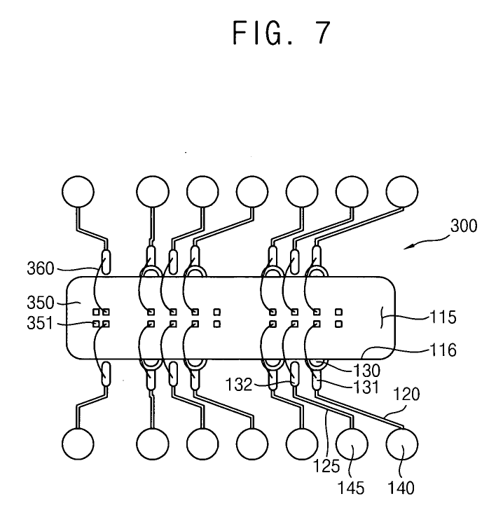

FIG. 6 is a cross-sectional view of a semiconductor package in accordance with an example embodiment. FIG. 7 is a bottom view of the semiconductor package in FIG. 6.

Referring to FIGS. 6 and 7, a semiconductor package 300 may include a circuit board 100, a semiconductor chip 350, a connecting wire 360, a molding member 370 and/or an external terminal 380. For example, the semiconductor package 300 may have a wire bonding ball array (WBGA) structure. The semiconductor package 300 may include the circuit board 100 shown in FIGS. 2 through 4, thus the same reference numerals refer to the same elements and any further explanation will be omitted here.

The semiconductor chip 350 may be disposed on a top surface of the circuit board 100. The semiconductor chip 350 may be adhered to the circuit board 100 by an elastic adhesive 355. For example, a plurality of the semiconductor chips 350 may be disposed on the circuit board 100.

The semiconductor chip 350 may include a plurality of connecting terminals 351. The connecting terminals 351 may be disposed near the slot 115 and may be exposed to the outside of the semiconductor package 300 through the slot 115. A plurality of the connecting wires 360 may be connected to the connecting terminals 351.

The connecting wires 360 may be extended downward through the slot 115 and may be connected to the first or second bond finger 131 or 132. The first and second bond fingers 131 and 132 may be electrically connected to the first and second conductive patterns 120 and 125, respectively. The first and second conductive patterns 120 and 125 may be electrically connected to the first and second landing pads 140 and 145, respectively, which may be formed on a bottom surface of the circuit board 100. The external terminals 380 may be formed on the bottom surface of the circuit board 100 and may make contact with the first and second landing pads 140 and 145.

The external terminals 380 may connect the semiconductor package 300 to a mounting board (not shown). The external terminals 380 may transfer power or signals from the mounting board to the semiconductor package 300, or ground the semiconductor package 300 through the mounting board. The first and second conductive patterns 120 and 125 may serve as a power wire, a ground wire or a signal wire depending on the type of the external terminal 380.

The semiconductor chip 350 and the connecting wires 360 formed on the circuit board 100 may be protected by the molding member 370. The molding member 370 may be formed on the circuit board 100 to a predetermined or desired thickness to cover the semiconductor chip 350 and the connecting wires 360. The molding member 370 may reduce or prevent contamination and/or damage to the semiconductor chip 350 and the connecting wires 360.

According to some example embodiments, a space for the first and second conductive patterns and on the circuit board may be secured even though the size of a semiconductor chip may be reduced. Thus, the semiconductor chip may be efficiently provided with power, stably grounded, and may input signals into or receive signals output from the external terminal.

According to some example embodiments, a space for conductive patterns on a circuit board may be enlarged. Thus, the conductive patterns may be disposed at the shortest distance therebetween without mutual interferences. Additionally, two external terminals may be connected to one bond finger so that characteristics of transferring power, grounding, or transferring signals of the circuit board may be improved. As a result, a semiconductor chip may be efficiently provided with power and stably grounded, and may input signals into or receive signals output from an external terminal.

The foregoing is illustrative of example embodiments and is not to be construed as limiting thereof. Although a few example embodiments have been described, those skilled in the art will readily appreciate that many modifications are possible without materially departing from the novel teachings and advantages of example embodiments. Accordingly, all such modifications are intended to be included within the scope as defined in the claims. In the claims, means-plus-function clauses are intended to cover the structures described herein as performing the recited function, and cover not only structural equivalents but also equivalent structures. Therefore, it is to be understood that the foregoing is illustrative of example embodiments and is not to be construed as limited to the specific example embodiments disclosed. Modifications to the disclosed example embodiments, other example embodiments, and equivalents thereof are intended to be included within the scope of the appended claims.

What is claimed is:

1. A circuit board comprising:
an insulation plate having at least one slot;
a first conductive pattern on the insulation plate; and
a plug in the insulation plate along a sidewall of the slot and electrically connected to the first conductive pattern.

2. The circuit board of claim 1, wherein the plug is received in a hole in the insulation plate along the sidewall of the slot.

3. The circuit board of claim 2, wherein the plug has a shape corresponding to that of a sidewall of the hole.

4. The circuit board of claim 2, wherein the plug fills up the hole.

5. The circuit board of claim 4, wherein the plug has a semi-circular cylindrical shape.

6. The circuit board of claim 2, wherein the plug protrudes from the sidewall of the hole.

7. The circuit board of claim 1, wherein the insulation plate includes a first conductive pad electrically connecting the first conductive pattern to an external terminal.

8. The circuit board of claim 7, wherein the external terminal is one of a power terminal for applying power to the first conductive pattern, a ground terminal for grounding the first conductive pattern, and a signal terminal for inputting electrical signals into the first conductive pattern or receiving electrical signals output from the first conductive pattern.

9. The circuit board of claim 7, wherein the first conductive pattern includes:
a first conductive line on an upper surface of the insulation plate electrically connected to an upper end of the plug;
a second conductive line on a lower surface of the insulation plate electrically connected to the first conductive pad; and
a contact plug through the insulation plate electrically connecting the first conductive line and the second conductive line.

10. The circuit board of claim 7, wherein a bond finger is on the lower surface of the insulation plate and is electrically connected to a lower end of the plug, the bond finger configured to be electrically connected to a terminal of a semiconductor chip.

11. The circuit board of claim 1, wherein the first conductive pattern is in the insulation plate.

12. The circuit board of claim 1, wherein the insulation plate includes a plurality of slots and a plurality of conductive patterns, and wherein at least one of the plurality of conductive patterns is disposed between at least two of the plurality of slots.

13. The circuit board of claim 1, further comprising a second conductive pattern on the lower surface of the insulation plate.

14. The circuit board of claim 13, wherein the insulation plate includes a second conductive pad electrically connecting the second conductive pattern to an external terminal.

15. A semiconductor package comprising:
the circuit board of claim 1; and
a semiconductor chip disposed on the circuit board, wherein a connecting terminal of the semiconductor chip is exposed through the slot, and wherein the connecting terminal is electrically connected to the plug.

16. The semiconductor package of claim 15, further comprising a molding member on the circuit board covering the semiconductor chip.

17. The semiconductor package of claim 15, wherein the first conductive pattern is one of a power wire for applying power to the semiconductor chip, a ground wire for grounding the semiconductor chip, and a signal wire for inputting electrical signals to the semiconductor chip or receiving electrical signals output from the semiconductor chip.

18. The semiconductor package of claim 15, wherein the insulation plate includes a plurality of slots and a plurality of conductive patterns, and wherein at least one of the plurality of conductive patterns is disposed between at least two of the plurality of slots.

19. The semiconductor package of claim 15, wherein the insulation plate includes a third conductive pad electrically connected to the first conductive pattern, further comprising an external terminal on the third conductive pad.

20. A method of manufacturing a circuit board, comprising:
forming a first conductive pattern on an insulation plate;
forming a plug through the insulation plate, the plug being electrically connected to the first conductive pattern; and
exposing the plug by forming a slot through the insulation plate.

21. The method of claim 20, wherein forming the plug includes forming a hole through the insulation plate, and forming the plug in the hole using a conductive material.

22. The method of claim 20, wherein forming the slot includes removing a portion of the plug.

23. The method of claim 20, further comprising forming a first conductive pad on the insulation plate, the first conductive pad electrically connecting the first conductive pattern to an external terminal.

24. The method of claim 23, wherein forming the first conductive pattern includes:
forming a first conductive line on an upper surface of the insulating plate electrically connected to an upper end of the plug;
forming a second conductive line on a lower surface of the insulating plate electrically connected to the first conductive pad; and
forming a contact plug through the insulation plate electrically connecting the first conductive line and the second conductive line.

25. The method of claim 23, further comprising forming a bond finger on the lower surface of the insulation plate, the bond finger configured to be electrically connected to a lower end of the plug and a connecting terminal of a semiconductor chip.

26. The method of claim 20, further comprising forming a second conductive pattern on the lower surface of the insulation plate.

27. The method of claim 26, further comprising forming a second conductive pad on the insulation plate, the second conductive pad electrically connecting the second conductive pattern to an external terminal.
